(19) United States
(12) Patent Application Publication
(10) Pub. No.: US 2013/0100633 A1
(43) Pub. Date: Apr. 25, 2013

(54) CONNECTOR MOUNTING DEVICE AND ELECTRONIC DEVICE WITH CONNECTOR MOUNTING DEVICE

(71) Applicants: ZHI-PING WU, Wuhan City (CN); XIAO-LI ZHANG, Wuhan City (CN)

(72) Inventors: ZHI-PING WU, Wuhan City (CN); XIAO-LI ZHANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/480,582

(22) Filed: May 25, 2012

(30) Foreign Application Priority Data
Oct. 25, 2011 (CN) 201110327497.4

(51) Int. Cl. H05K 7/14

(52) U.S. Cl. 361/809

(57) ABSTRACT

A connector mounting device includes a bracket for receiving an electronic module. The bracket includes a front plate; a limiting portion, a positioning piece and a blocking piece extend from the front plate. A sliding channel is defined between the limiting portion and the positioning piece and adapted for slidably receiving a connector. A resilient piece extends from the limiting portion. The resilient piece is located in a first end of the sliding channel. The blocking piece is located in a second end of the sliding channel. The first end is opposite to the second end. The blocking piece and the resilient piece are adapted to block the connector therebetween, to prevent the connector from sliding along the sliding channel.

### BACKGROUND

1. Technical Field

The present disclosure relates to an electronic device with a connector mounting device.

2. Description of Related Art

An electronic module, such as a hard disk drive, is mounted in an electronic device, such as a computer or a server. The electronic module may be coupled with a power cable plug and a data cable plug of a motherboard. The power cable plug and the data cable plug are tied together with a lot of other plugs and placed randomly in the electronic device. The power cable plug and the data cable plug are coupled with the electronic module, after the electronic module is secured to a chassis of the electronic device. However, the plurality of plugs may easily become a confusing mass of cables and plugs. Therefore, an improved electronic device is desired within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device with a connector mounting device in accordance with an embodiment.

FIG. 2 is an enlarged view of a circled portion II of FIG. 1.

FIG. 3 is an assembled, isometric view of the electronic device with the connector mounting device of FIG. 1.

FIG. 4 is an enlarged view of a circled portion IV of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

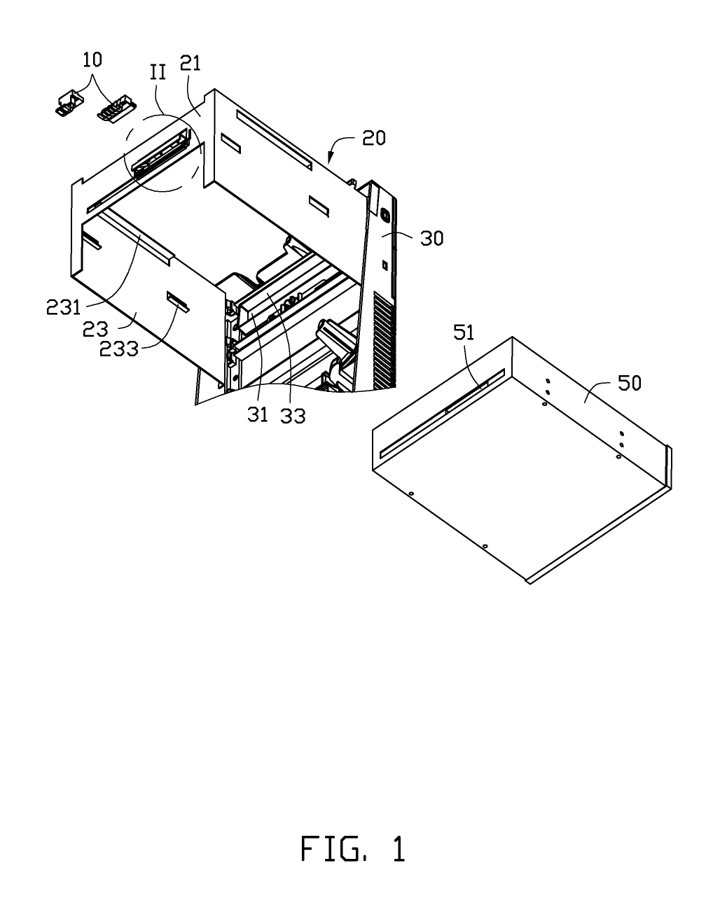

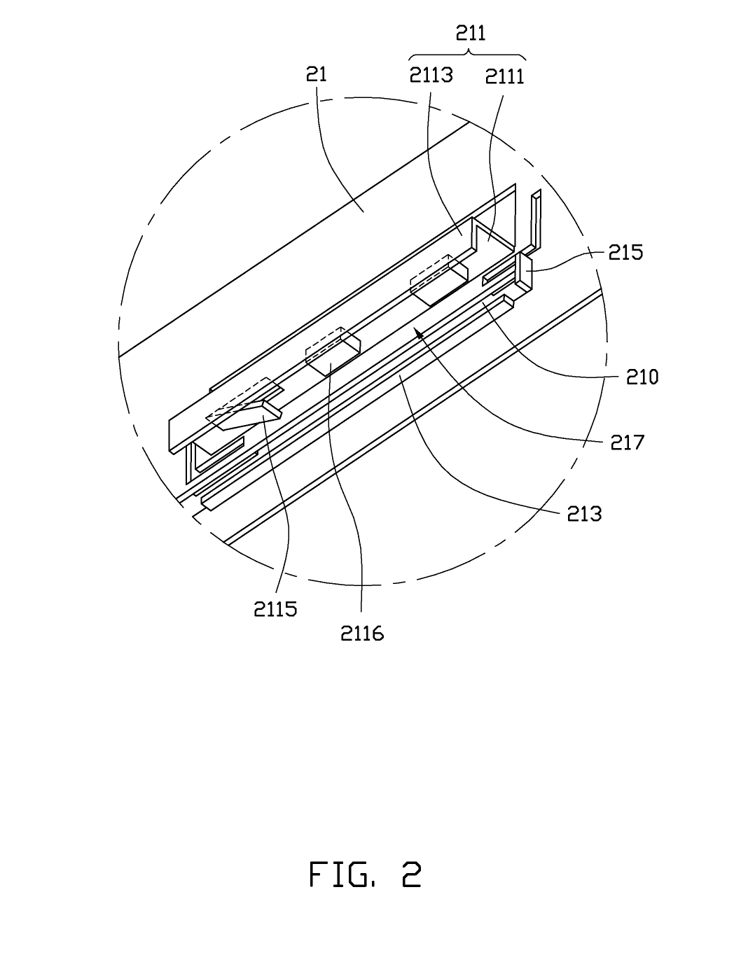

FIG. 1 and FIG. 2 show a connector mounting device in accordance with an embodiment, for securing a plurality of connectors 10. The mounting device includes a bracket 20.

The bracket 20 can be secured to a mounting plate 30 and used for mounting an electronic module 50. In one embodiment, the mounting plate 30 is a front plate of a chassis of a computer or a server, and the electronic module 50 is a data storage device.

The bracket 20 includes a front plate 21 and two side plates 23. The two side plates 23 are secured to the mounting plate 30. In one embodiment, the front plate 21 is substantially perpendicular to the two side plates 23. The front plate 21 defines an installation opening 210.

A limiting portion 211, a positioning piece 213 and a blocking piece 215 extend outwards from an outer surface of the front plate 21. The positioning piece 213 extends from a bottom edge of the installation opening 210. The blocking piece 215 extends from a side edge of the installation opening 210. The side edge is adjacent to the bottom edge. The limiting portion 211 includes a limiting piece 2111 and a flange 2113. The limiting piece 2111 extends from the front plate 21. The flange 2113 extends from the limiting piece 2111 towards the positioning piece 213. In one embodiment, the limiting piece 2111 is substantially parallel to the positioning piece 213, and the flange 2113 is substantially parallel to the limiting piece 2111. The blocking piece 215 is located on a side of the limiting portion 211 and the positioning piece 213. In one embodiment, the blocking piece 215 is substantially perpendicular to the flange 2113 and the positioning piece 213. A sliding channel 217 is defined between the limiting portion 211 and the positioning piece 213 for the connectors 10 to slide along. A length of the installation opening 210 is greater than a length of the sliding channel 217. A resilient piece 2115 extends obliquely from the limiting piece 2111 and towards the blocking piece 215. An acute angle is defined between the resilient piece 2115 and the limiting piece 2111. Two protrusions 2116 are located on the limiting piece 2111 facing the positioning piece 213. The two protrusions 2116 are located between the resilient piece 2115 and the blocking piece 215. A first limiting piece 231 and two second limiting pieces 233 extend from an inner surface of each of the two side plate 23. In one embodiment, the first limiting piece 231 is substantially parallel to the two second limiting pieces 233 and perpendicular to the side plate 23. A sliding slot (not labeled) is defined between the first limiting piece 231 and the two second limiting pieces 233 for the electronic module 50 to slide along.

The mounting plate 30 defines an opening 31 for the electronic module 50 to be inserted into the bracket 20. The opening 31 is aligned with the sliding slot. An installation piece 33 extends from edges of the opening 31. In one embodiment, the opening 31 is rectangular, and the installation piece 33 is substantially perpendicular to the front plate 21.

The electronic module 50 includes an inserting end 51 coupled to the connector 10.

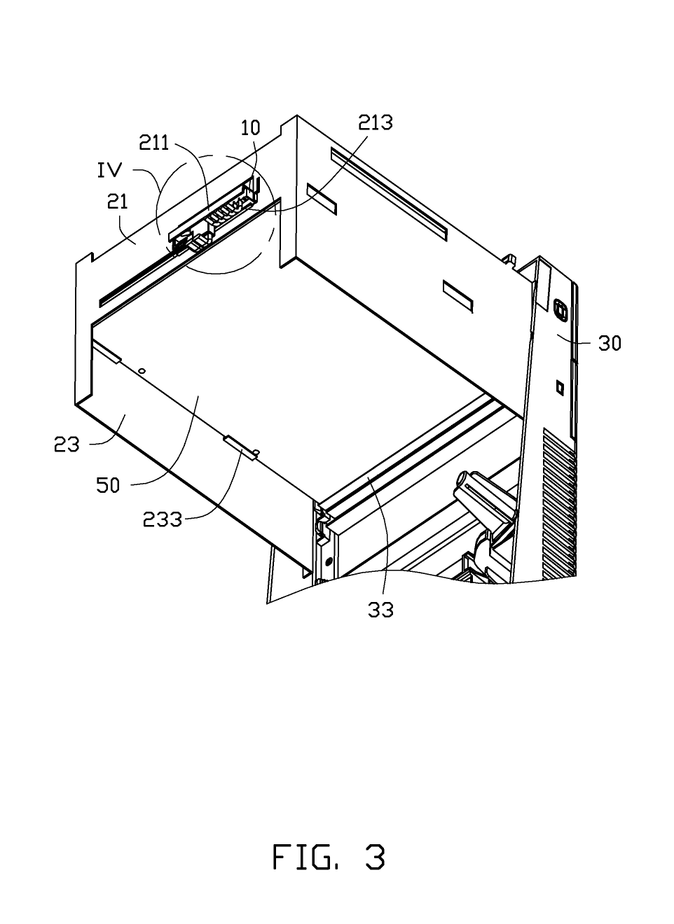

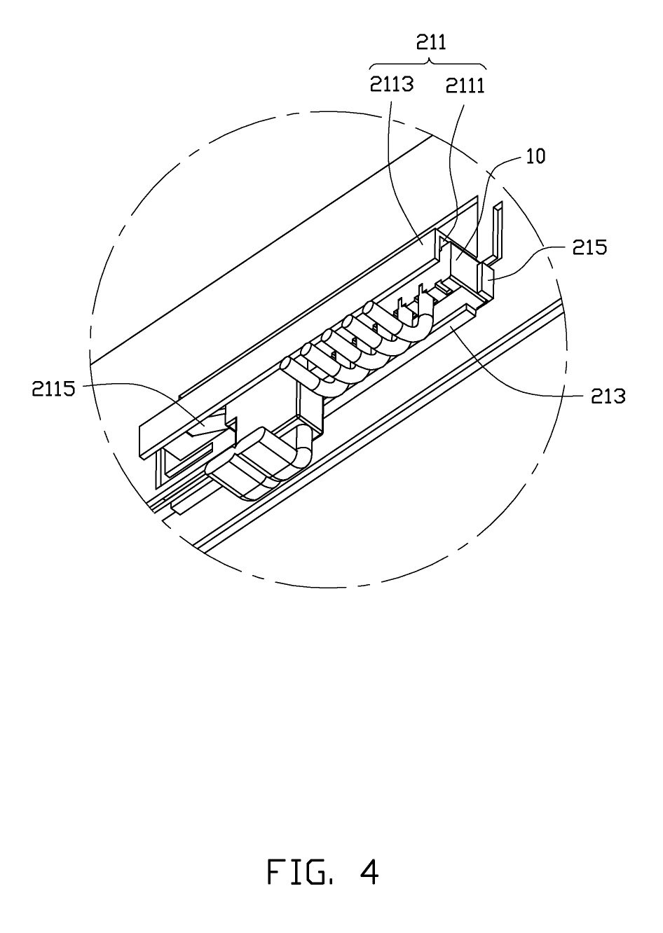

FIG. 3 and FIG. 4 show that, in assembly, the connector 10 is moved to be adjacent to the front plate 21 and the resilient piece 2115. The connector 10 is partially inserted into the installation opening 210 and placed in the sliding channel 217. The connector 10 is moved towards the blocking piece 215. The resilient piece 2115 is elastically deformed upwards to the limiting piece 2111. The connector 10 is slid over the resilient piece 2115, until the connector 10 is blocked by the blocking piece 215. The resilient piece 2115 rebounds to block the connector 10 between the resilient piece 2115 and the blocking piece 215. The connector 10 is further secured between the two protrusions 2116 and the positioning piece 213. The electronic module 50 is slid from the opening 31 along the sliding slot between the first limiting piece 231 and the two second limiting pieces 233, until the electronic module 50 abuts the front plate 21. In this position, the inserting end 51 is coupled with the connector 10.

Thus, when in assembly of the electronic module 50, the electronic module 50 can be coupled with the connector 10 at the same time.

In disassembly, the electronic module 50 is pulled to disengage from the connector 10 and removed from the bracket 20. The resilient piece 2115 is pressed to be elastically deformed towards the limiting piece 2111, and then the connector 10 can be removed from the bracket 20.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A connector mounting device, comprising:
a bracket for receiving an electronic module and comprising a front plate; a limiting portion, a positioning piece and a blocking piece extending from the front plate;
wherein a sliding channel is defined between the limiting portion and the positioning piece, and the sliding channel is adapted for slidably receiving a connector; a resilient piece extends from the limiting portion, and the resilient piece is located in a first end of the sliding channel; the blocking piece is located in a second end of the sliding channel, the first end being opposite to the second end; and the blocking piece and the resilient piece are adapted to block the connector therebetween thereby preventing the connector from sliding along the sliding channel.

2. The connector mounting device of claim 1, wherein the limiting portion comprises a limiting piece and a flange, the limiting piece extends from the front plate, and the flange extends from the limiting piece; the limiting piece is substantially perpendicular to the front plate and parallel to the positioning piece; and the flange is substantially parallel to the front plate.

3. The connector mounting device of claim 2, wherein the blocking piece is substantially perpendicular to the limiting piece and the positioning piece.

4. The connector mounting device of claim 3, wherein the resilient piece extends obliquely from the limiting piece, and an acute angle is defined between the resilient piece and the limiting piece.

5. The connector mounting device of claim 2, wherein a protrusion is located on the limiting piece and faces the positioning piece, the protrusion is located in the sliding channel, and the protrusion and the positioning piece are adapted to abut the connector therebetween.

6. The connector mounting device of claim 1, wherein the front plate defines an installation opening, the blocking piece extends from a side edge of the installation opening, and the positioning piece extends from a bottom edge of the installation opening; the side edge is adjacent to the bottom edge; and the installation opening is configured for the connector to be inserted into and coupled with the electronic module.

7. The connector mounting device of claim 6, wherein a length of the installation opening is greater than a length of the sliding channel.

8. The connector mounting device of claim 1, wherein the bracket further comprises two side plates connects the front plate, a first limiting piece and a second limiting piece extend from each of the two side plates, and the first limiting piece is substantially parallel to the second limiting piece; and the first limiting piece and the second limiting piece are adapted for the electronic module to slide therebetween.

9. The connector mounting device of claim 8, further comprising a mounting plate; the two side plates are secured to the mounting plate; and the mounting plate defines an opening for the electronic module to pass through.

10. The connector mounting device of claim 9, wherein an installation piece extends from each edge of the opening, the installation piece is substantially perpendicular to the mounting plate, and the installation piece is adapted to assist the electronic module when the electronic module is slid from the opening.

11. An electronic device, comprising:
mounting plate defining an opening;
an electronic module comprising an inserting end;
a connector; and
a bracket secured to the mounting plate and comprising a front plate opposite to the mounting plate; and a limiting portion, a positioning piece and a blocking piece extending from the front plate;
wherein a sliding channel is defined between the limiting portion and the positioning piece, and the connector is slidably received in the sliding channel; a resilient piece extends from the limiting portion, and the resilient piece is located in a first end of the sliding channel; the blocking piece is located in a second end of the sliding channel, the first end being opposite to the second end; and the connector is located between the blocking piece and the resilient piece and is prevented from being slid along the sliding channel; the electronic module is received in the bracket through the opening, and the inserting end is coupled with the connector when the electronic module is received in the bracket.

12. The electronic device of claim 11, wherein the limiting portion comprises a limiting piece and a flange, the limiting piece extends from the front plate, and the flange extends from the limiting piece; the limiting piece is substantially perpendicular to the front plate and parallel to the positioning piece; and the flange is substantially parallel to the front plate.

13. The electronic device of claim 12, wherein the blocking piece is substantially perpendicular to the limiting piece and the positioning piece.

14. The electronic device of claim 13, wherein the resilient piece extends obliquely from the limiting piece, and an acute angle is defined between the resilient piece and the limiting piece.

15. The electronic device of claim 12, wherein a protrusion is located on the limiting piece and faces the positioning piece, the protrusion is located in the sliding channel, and the connector is located between the protrusion and the positioning piece.

16. The electronic device of claim 11, wherein the front plate defines an installation opening, the blocking piece extends from a side edge of the installation opening, and the positioning piece extends from a bottom edge of the installation opening; and the side edge is adjacent to the bottom edge; and connector is partially received in the bracket through the installation opening and coupled with the electronic module.

17. The electronic device of claim 16, wherein a length of the installation opening is greater than a length of the sliding channel.

18. The electronic device of claim 11, wherein the bracket further comprises two side plates connects the front plate, a first limiting piece and a second limiting piece extend from each of the two side plates, and the first limiting piece is substantially parallel to the second limiting piece; and the electronic module is located and slid between the first limiting piece and the second limiting piece.

19. electronic device of claim 18, wherein the two side plates are secured to the mounting plate.

20. The electronic device of claim 19, wherein an installation piece extends from each edge of the opening, the installation piece is substantially perpendicular to the mounting plate, and the installation piece assists the electronic module when the electronic module is slid from the opening.
